(19) United States
(12) Patent Application Publication
(10) Pub. No.: US 2024/0393686 A1
(43) Pub. Date: Nov. 28, 2024

(54) PHOTOSENSITIVE RESIN COMPOSITION, PHOTOSENSITIVE RESIN FILM, MULTILAYERED PRINTED WIRING BOARD, SEMICONDUCTOR PACKAGE, AND METHOD FOR PRODUCING MULTILAYERED PRINTED WIRING BOARD

(71) Applicant: Resonac Corporation, Tokyo (JP)

(72) Inventors: Hideyuki KATAGI, Tokyo (JP); Kohei ABE, Tokyo (JP); Yuko KONNO, Tokyo (JP); Ryo YUKIOKA, Tokyo (JP); Noriyo KIMURA, Tokyo (JP); Tomohiro AYUGASE, Tokyo (JP)

(21) Appl. No.: 18/687,238

(22) PCT Filed: Aug. 30, 2021
(86) PCT No.: PCT/JP2021/031678

§ 371 Date: Feb. 27, 2024

(51) Int. Cl. G03F 7/038; G03F 7/004; G03F 7/029; H05K 3/46

(52) U.S. Cl. CPC G03F 7/0387; G03F 7/0042; G03F 7/029; G03F 7/0382; G03F 7/0388; H05K 3/4626

(57) ABSTRACT

Provided is a photosensitive resin composition containing: (A) a photopolymerizable compound having an ethylenically unsaturated group and an acidic substituent; (B) a (meth)acrylate compound having two or more (meth)acryloyl groups; (C) a compound having two or more ethylenically unsaturated groups other than the (meth)acryloyl groups; (D) a photopolymerization initiator, and (E) an organic peroxide.

### TECHNICAL FIELD

The present disclosure relates to a photosensitive resin composition, a photosensitive resin film, a multilayered printed wiring board and a semiconductor package, and a method for producing the multilayered printed wiring board.

### BACKGROUND ART

In recent years, miniaturization and an increase in performance of electronic instruments are advanced, and in multilayered printed wiring boards, densification owing to an increase in the number of circuit layers, refinement of wirings, and the like proceeds. In particular, densification of a semiconductor package substrate on which a semiconductor chip is mounted, such as ball grid array (BGA) and chip size package (CSP), is conspicuous, and in addition to the refinement of wiring, thinning of an interlayer insulating layer and a reduction in the diameter of a via for interlayer connection are demanded.

Examples of a method for producing a printed wiring board conventionally used include a method for producing a multilayered printed wiring board by a build-up process for successively laminating an interlayer insulating layer and a conductor circuit layer (see, for example, PTL 1). In the multilayered printed wiring board, following the refinement of a circuit, a semi-additive process for forming a circuit by plating becomes the mainstream.

In the conventional semi-additive process, for example, (1) a thermosetting resin film is laminated on a conductor circuit, and the thermosetting resin film is cured under heating, to form an interlayer insulating layer. (2) Subsequently, a via for interlayer connection is formed by laser processing, followed by performing a desmear treatment and a roughening treatment by an alkaline permanganate treatment, and the like. (3) Thereafter, a substrate is subjected to an electroless copper plating treatment, and after forming a pattern using a resist, a copper electroplating treatment is performed to form a circuit layer of copper. (4) Subsequently, resist is peeled, and an electroless layer is subjected to flash etching, to form a circuit.

As a method for forming a via in an interlayer insulating layer formed from a thermosetting resin film, laser processing is the mainstream, but a reduction in the diameter of a via by laser irradiation nearly reaches its limit. For formation of vias with a laser processing device, it is necessary to form via holes one by one. Therefore, when a large number of vias need to be formed for densification, there is such a problem that a lot of time is required for the formation of the vias, so that the production cost is high and the production efficiency is poor.

Under such circumstances, as a method capable of collectively forming a large number of vias, a method of collectively forming a plurality of reduced-diameter vias by a photolithography method using a photosensitive resin composition that contains an acid-modified vinyl group-containing epoxy resin, a photopolymerizable compound, a photopolymerization initiator, an inorganic filler, and a silane compound, and in which the content of the inorganic filler is 10 to 80% by mass is proposed (see, for example, PTL 2).

### CITATION LIST

### Patent Literature

PTL 1: JPH07-304931A
PTL 2: JP2017-116652A

### SUMMARY OF INVENTION

### Technical Problem

In recent years, substrate materials that are adapted to a fifth generation mobile communication system (5G) antenna for high-frequency-band radio wave and a millimeter wave radar for radio wave of a frequency band of 30 to 300 GHz are demanded. Therefore, improvement in dielectric properties for reducing transmission loss of a high-frequency signal, that is, a reduction in dielectric dissipation factor is required. However, the technique in PTL 2 does not meet such a demand.

In view of the circumstances, an object of an embodiment is to provide a photosensitive resin composition having an excellent dielectric dissipation factor (Df), a photosensitive resin film formed using the photosensitive resin composition, a multilayered printed wiring board and a method for producing the multilayered printed wiring board, and a semiconductor package.

### Solution to Problem

The present inventors have studied to solve the aforementioned problems, and as a result, found that the problems can be solved by the following embodiments.

Specifically, the embodiments relate to [1] to below.
[1] A photosensitive resin composition containing:
(A) a compound having an acidic substituent and a (meth)acryloyl group;
(B) a (meth)acrylate compound having two or more (meth)acryloyl groups:
(C) a compound having two or more ethylenically unsaturated groups other than the (meth)acryloyl groups:
(D) a photopolymerization initiator; and
(E) an organic peroxide.
[2] The photosensitive resin composition according to [1], wherein the component (C) is a compound having one or more selected from the group consisting of a maleimide group, an allyl group, a nadimide group, and a vinyl group as the ethylenically unsaturated groups other than the (meth)acryloyl groups.
[3] The photosensitive resin composition according to [1], wherein the component (C) is a compound having two or more maleimide groups.
[4] The photosensitive resin composition according to [1], wherein the component (C) is a compound having two or more allyl groups.
[5] The photosensitive resin composition according to [1], wherein the component (C) is a compound having two or more nadimide groups.
[6] The photosensitive resin composition according to [1], wherein the component (C) is a compound having two or more vinyl groups.
[7] The photosensitive resin composition according to any one of [1] to [6], further containing (F) an inorganic filler.
[8] The photosensitive resin composition according to any one of [1] to [7], further containing (G) a thiol compound.
[9] The photosensitive resin composition according to any one of [1] to [8] which is for photo via formation.
[10] The photosensitive resin composition according to any one of [1] to [9], wherein a dielectric dissipation factor (Df) at 10 GHz of a cured product is 0.0040 to 0.0100.
[11] A photosensitive resin film formed using the photosensitive resin composition according to any one of [1] to [10].
[12] The photosensitive resin film according to [11], having a thickness of 1 to 100 μm.
[13] A multilayered printed wiring board including an interlayer insulating layer formed using the photosensitive resin composition according to any one of [1] to or the photosensitive resin film according to or [12].
[14] A semiconductor package including the multilayered printed wiring board according to [13].
[15] A method for producing a multilayered printed wiring board including (1) to (4) below:
(1): laminating the photosensitive resin film according to or on one surface or both surfaces of a circuit substrate:
(2): exposing and developing the photosensitive resin film laminated in (1), to form an interlayer insulating layer having a via:
(3): heating and curing the interlayer insulating layer having a via; and
(4): forming a circuit pattern on the interlayer insulating layer.

### Advantageous Effects of Invention

According to the embodiments, a photosensitive resin composition having an excellent dielectric dissipation factor (Df), a photosensitive resin film formed using the photosensitive resin composition, a multilayered printed wiring board and a method for producing the multilayered printed wiring board, and a semiconductor package can be provided.

### BRIEF DESCRIPTION OF DRAWINGS

FIG. 1 is a schematic view illustrating an aspect of a process of producing a multilayered printed wiring board using a photosensitive resin film of an embodiment as a material for an interlayer insulating layer.

### DESCRIPTION OF EMBODIMENTS

In a numerical value range described in this description, the lower limit value and the upper limit value of the numerical value range may be substituted by each value described in Examples. In addition, the lower limit value and the upper limit value in the numerical value range are each arbitrarily combined with the lower limit value or the upper limit value of another numerical value range. In an expression of the numerical value range “AA to BB”, the numerical values AA and BB that are both ends are contained in the numerical value range as the lower limit value and the upper limit value, respectively.

In the description, for example, the expression “10 or more” means 10 and a numerical value exceeding 10. In the case of different numerical values, this is also adopted. For example, the expression “10 or less” means 10 and a numerical value less than 10. In the case of different numerical values, this is also adopted.

In the description, if a plurality of types of substances corresponding to each of components in a photosensitive resin composition exist, the content of each of the components in the photosensitive resin composition means the total content of the substances existing in the photosensitive resin composition unless otherwise indicated.

In the description, the term “ring-forming carbon atom number” is the number of carbon atoms necessary for forming the ring, but the number of carbon atoms of a substituent of the ring is not included. For example, in both a cyclohexane skeleton and a methylcyclohexane skeleton, the ring-forming carbon atom number is 6.

The expression “(meth)acryl XX” means one or both of acryl XX and methacryl XX corresponding to it. Further, a “(meth)acryloyl group” means one or both of an acryloyl group and a methacryloyl group.

In the description, for example, as for the expression “layer”, like an interlayer insulating layer, the layer includes an aspect that is a solid layer, an aspect that is a partial island shape, but not the solid layer, an aspect that has a hole, and an aspect that has an unclear interface between the aspect and an adjacent layer.

An embodiment also includes aspects in which matters described in the description are optionally combined.

### [Photosensitive Resin Composition]

A photosensitive resin composition of the embodiment is a photosensitive resin composition containing (A) a compound having an acidic substituent and a (meth)acryloyl group, (B) a (meth)acrylate compound having two or more (meth)acryloyl groups, (C) a compound having two or more ethylenically unsaturated groups other than the (meth)acryloyl groups, (D) a photopolymerization initiator, and (E) an organic peroxide.

In the description, the aforementioned components are occasionally abbreviated as and referred to as “the component (A)”, and the like, as appropriate, and other components are also occasionally abbreviated in the same way.

### <(A) Compound Having Acidic Substituent and (Meth)Acryloyl Group>

The component (A) is the compound having an acidic substituent and a (meth)acryloyl group.

The component (A) is a compound that has a (meth)acryloyl group and undergoes a photo-radical polymerization reaction.

One type of the component (A) may be used alone, or two or more types thereof may be used in combination.

From the viewpoint of alkaline development, the component (A) has an acidic substituent.

Examples of the acidic substituent of the component (A) include a carboxy group, a sulfonic acid group, and a phenolic hydroxy group. Of these, from the viewpoint of alkaline development, a carboxy group is preferred.

From the viewpoint of dielectric properties and alkaline development, the acid value of the component (A) is preferably 20 to 200 mg KOH/g, more preferably 50 to 160 mg KOH/g, and still more preferably 90 to 120 mg KOH/g.

The acid value of the component (A) can be measured by a method described in Examples.

From the viewpoint of heat resistance and insulation reliability, the weight average molecular weight of the component (A) is preferably 500 to 30,000, more preferably 700 to 10,000, and still more preferably 1,000 to 5,000.

In the description, the weight average molecular weight is a value determined in terms of standard polystyrene by gel permeation chromatography (GPC) using tetrahydrofuran as a solvent. More specifically, it is a value measured according to a method described in Examples.

From the viewpoint of a low dielectric constant and a reduction in dielectric dissipation factor, the component (A) preferably contains an alicyclic skeleton.

From the viewpoint of resolution and dielectric properties, an alicyclic skeleton of the component (A) is preferably an alicyclic skeleton having 5 to 20 ring-forming carbon atoms, more preferably an alicyclic skeleton having 5 to 18 ring-forming carbon atoms, still more preferably an alicyclic skeleton having 6 to 16 ring-forming carbon atoms, particularly preferably an alicyclic skeleton having 7 to 14 ring-forming carbon atoms, and the most preferably an alicyclic skeleton having 8 to 12 ring-forming carbon atoms.

From the viewpoint of resolution and dielectric properties, the alicyclic skeleton of the component (A) is preferably composed of 2 or more rings, more preferably composed of 2 to 4 rings, and still more preferably composed of 3 rings. Examples of the alicyclic skeleton composed of 2 or more rings include a norbornane skeleton, a decalin skeleton, a bicycloundecane skeleton, and a saturated dicyclopentadiene skeleton. Of these, from the viewpoint of resolution and dielectric properties, a saturated dicyclopentadiene skeleton is preferred.

From the same viewpoint, the component (A) preferably contains an alicyclic skeleton represented by the following general formula (A-1).

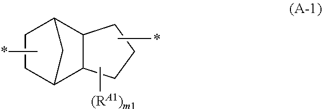

In the formula, R^{A1} represents an alkyl group having 1 to 12 carbon atoms and may be substituted in any site in the alicyclic skeleton; m¹ is an integer of 0 to 6; and * represents a binding site.

Examples of the alkyl group having 1 to 12 carbon atoms represented by R^{A1} in the general formula (A-1) include a methyl group, an ethyl group, a n-propyl group, an isopropyl group, a n-butyl group, an isobutyl group, a t-butyl group, and a n-pentyl group. The alkyl group is preferably an alkyl group having 1 to 6 carbon atoms, more preferably an alkyl group having 1 to 3 carbon atoms, and still more preferably a methyl group.
m¹ is an integer of 0 to 6, preferably an integer of 0 to 2, and more preferably 0.
When m¹ is an integer of 2 to 6, a plurality of R^{A1}'s may be the same as or different from each other. R^{A1}'s may be substituted on the same carbon atoms within a possible range or may be substituted on different carbon atoms from each other.
* is a binding site to another structure, and binding may be made by any carbon atom on the alicyclic skeleton; however, binding is preferably made by the carbon atom expressed by 1 or 2 and the carbon atom expressed by 3 or 4 in the following general formula (A-1′).

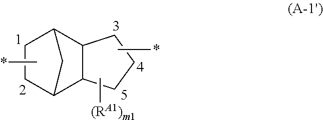

In the formula, R^{A1}'s, m¹, and * are the same as those in the general formula (A-1).

The component (A) is preferably a compound (hereinafter also referred to as “acid-modified (meth)acryloyl group-containing epoxy resin derivative”) obtained by allowing a compound (hereinafter sometimes referred to as component (A′)) obtained by modifying (a1) an epoxy resin with (a2) a (meth)acryloyl group-containing organic acid to react with (a3) a saturated group or unsaturated group-containing polybasic acid anhydride.

Hereinafter, a suitable aspect of the component (A) obtained from the epoxy resin (a1), the (meth)acryloyl group-containing organic acid (a2), and the saturated group or unsaturated group-containing polybasic acid anhydride (a3) will be described.

((a1) Epoxy Resin)

The epoxy resin (a1) is preferably an epoxy resin having two or more epoxy groups.

One type of the epoxy resin (a1) may be used alone, or two or more types thereof may be used in combination.

The epoxy resin (a1) is classified into a glycidyl ether type epoxy resin, a glycidyl amine type epoxy resin, a glycidyl ester type epoxy resin, and the like. Of these, a glycidyl ether type epoxy resin is preferred.

The epoxy resin (a1) can be classified depending upon a difference of the main skeleton into various epoxy resins: an epoxy resin having an alicyclic skeleton, a novolak type epoxy resin, a bisphenol type epoxy resin, an aralkyl type epoxy resin, and the other epoxy resin. Of these, an epoxy resin having an alicyclic skeleton and a novolak type epoxy resin are preferred.

### -Epoxy Resin Having Alicyclic Skeleton-

The alicyclic skeleton of the epoxy resin having an alicyclic skeleton is described in the same manner as the alicyclic skeleton of the component (A) as described above, and a preferred aspect thereof is also the same.

The epoxy resin having an alicyclic skeleton is preferably an epoxy resin represented by the following general formula (A-2).

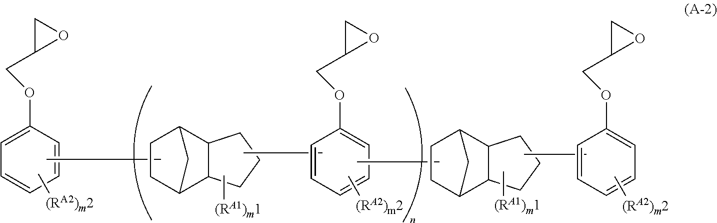

In the formula, R^{A1}'s each independently represent an alkyl group having 1 to 12 carbon atoms and may be substituted in any site in the alicyclic skeleton; R^{A2}'s each independently represent an alkyl group having 1 to 12 carbon atoms; m¹ is an integer of 0 to 6; m² is an integer of 0 to 3; and n is 0 to 50.

In the general formula (A-2), R^{A1}'s are the same as R^{A1}'s in the general formula (A-1), and a preferred aspect thereof is also the same.

Examples of the alkyl group having 1 to 12 carbon atoms represented by R^{A2} in the general formula (A-2) include a methyl group, an ethyl group, a n-propyl group, an isopropyl group, a n-butyl group, an isobutyl group, a t-butyl group, and a n-pentyl group. The alkyl group is preferably an alkyl group having 1 to 6 carbon atoms, more preferably an alkyl group having 1 to 3 carbon atoms, and still more preferably a methyl group.

In the general formula (A-2), m¹ is the same as m¹ in the general formula (A-1), and a preferred aspect thereof is also the same.

In the general formula (A-2), m² is an integer of 0 to 3, preferably 0 or 1, and more preferably 0.

In the general formula (A-2), n represents the number of structural unit within parentheses and is 0 to 50. In general, the epoxy resin is a mixture of epoxy resins that are different in the number of the structural unit within the parentheses. In this case, n is represented by an average value of the mixture. n is preferably 0 to 30.

As the epoxy resin having an alicyclic skeleton, a commercially available product may be used. Examples of the commercially available product include “XD-1000” (trade name, manufactured by Nippon Kayaku Co., Ltd.) and “EPICLON (registered trademark) HP-7200” (trade name, manufactured by DIC Corporation).

### -Novolak Type Epoxy Resin-

Examples of the novolak type epoxy resin include bisphenol novolak type epoxy resins such as a bisphenol A novolak type epoxy resin, a bisphenol F novolak type epoxy resin, and a bisphenol S novolak type epoxy resin: a phenol novolak type epoxy resin, a cresol novolak type epoxy resin, a biphenyl novolak type epoxy resin, and a naphthol novolak type epoxy resin.

The novolak type epoxy resin is preferably an epoxy resin having a structural unit represented by the following general formula (A-3).

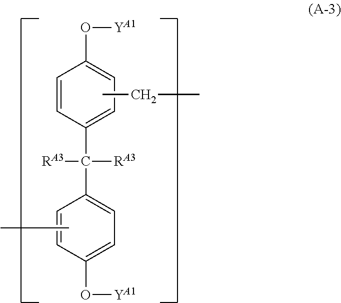

In the formula, R^{A3}'s each independently represent a hydrogen atom or a methyl group, Y^{A1}'s each independently represent a hydrogen atom or a glycidyl group, and at least one of the two Y^{A1}'s is a glycidyl group.

From the viewpoint of resolution, all R^{A3}'s are preferably a hydrogen atom. From the same viewpoint, all Y^{A1}'s are preferably a glycidyl group.

The number of the structural unit in the epoxy resin (a1) having the structural unit represented by the general formula (A-3) is 1 or more, preferably 10 to 100, more preferably 13 to 80, and still more preferably 15 to 70. When the number of the structural unit is within the aforementioned range, the adhesion strength to copper plating, heat resistance, and insulation reliability tend to be improved.

The epoxy resin having the structural unit represented by the general formula (A-3) wherein all R^{A3}'s are a hydrogen atom and all Y^{A1}'s are a glycidyl group is commercially available as “EXA-7376” series (trade name, manufactured by DIC Corporation), and the epoxy resin having the structural unit represented by the general formula (A-3) wherein all R^{A3}'s are a methyl group and all Y^{A1}'s are a glycidyl group is commercially available as “EPON SU8” series (trade name, manufactured by Mitsubishi Chemical Corporation).

Examples of the bisphenol type epoxy resin include a bisphenol A type epoxy resin, a bisphenol F type epoxy resin, a bisphenol S type epoxy resin, and 3,3′,5,5′-tetramethyl-4,4′-diglycidyloxy diphenylmethane.

Examples of the aralkyl type epoxy resin include a phenol aralkyl type epoxy resin, a biphenyl aralkyl type epoxy resin, and a naphthol aralkyl type epoxy resin.

Examples of the other epoxy resin include a stilbene type epoxy resin, a naphthalene type epoxy resin, a naphthylene ether type epoxy resin, a biphenyl type epoxy resin, a dihydroanthracene type epoxy resin, a cyclohexane dimethanol type epoxy resin, a trimethylol type epoxy resin, an alicyclic epoxy resin, an aliphatic linear epoxy resin, a heterocyclic epoxy resin, a spiro ring-containing epoxy resin, and a rubber-modified epoxy resin.

((a2) (Meth)Acryloyl Group-Containing Organic Acid)

The (meth)acryloyl group-containing organic acid (a2) is preferably a (meth)acryloyl group-containing monocarboxylic acid.

Examples of the (meth)acryloyl group-containing monocarboxylic acid include acrylic acid; acrylic acid derivatives such as a dimer of acrylic acid, methacrylic acid, β-furfurylacrylic acid, β-styrylacrylic acid, cinnamic acid, crotonic acid, and α-cyanocinnamic acid; half ester compounds that are a product of a reaction between a hydroxy group-containing acrylate and a dibasic acid anhydride; and half ester compounds that are a product of a reaction between a (meth)acryloyl group-containing monoglycidyl ether or a (meth)acryloyl group-containing monoglycidyl ester and a dibasic acid anhydride.

One type of the component (a2) may be used alone, or two or more types thereof may be used in combination.

The half ester compound is obtained by allowing one or more types of (meth)acryloyl group-containing compound selected from the group consisting of a hydroxy group-containing acrylate, a (meth)acryloyl group-containing monoglycidyl ether, and a (meth)acryloyl group-containing monoglycidyl ester to react with a dibasic acid anhydride. The reaction is preferably a reaction between the (meth)acryloyl group-containing compound and the dibasic acid anhydride at an equimolar ratio.

Examples of the hydroxy group-containing acrylate used for a synthesis of the half ester compound include hydroxyethyl (meth)acrylate, hydroxypropyl (meth)acrylate, hydroxy butyl (meth)acrylate, polyethylene glycol mono(meth)acrylate, trimethylolpropane di(meth)acrylate, pentaerythritol tri(meth)acrylate, and dipentaerythritol penta(meth)acrylate.

Examples of a vinyl group-containing monoglycidyl ether include glycidyl (meth)acrylate.

The dibasic acid anhydride used for the synthesis of the half ester compound may be one containing a saturated group or may be one containing an unsaturated group. Examples of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

The amount of the used component (a2) relative to one equivalent of epoxy group of the component (a1) in the reaction between the component (a1) and the component (a2) is preferably 0.6 to 1.1 equivalents, more preferably 0.8 to 1.05 equivalents, and still more preferably 1.0 equivalent. By performing the reaction between the component (a1) and the component (a2) at the aforementioned ratio, the polymerizability of the component (A) tends to be improved, to improve the resolution of the obtained photosensitive resin composition.

It is preferable that the component (a1) and the component (a2) be dissolved in an organic solvent and allowed to react with each other under heating. During the reaction, if necessary, a publicly known reaction catalyst, polymerization inhibitor, or the like may be used.

When as the component (a2), the (meth)acryloyl group-containing monocarboxylic acid is used, the component (A′) obtained by the reaction between the component (a1) and the component (a2) has a hydroxy group formed by a ring-opening addition reaction between an epoxy group of the component (a1) and a carboxy group of the component (a2). Subsequently, the component (A′) is allowed to further react with the component (a3), to obtain an acid-modified (meth)acryloyl group-containing epoxy resin derivative in which a hydroxy group of the component (A′) (including a hydroxy group originally present in the component (a1)) and an acid anhydride group of the component (a3) are half-esterified.

((a3) Polybasic Acid Anhydride)

The component (a3) may be one containing a saturated group or may be one containing an unsaturated group. Examples of the component (a3) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Of these, from the viewpoint of resolution, tetrahydrophthalic anhydride is preferred. One type of the component (a3) may be used alone, or two or more types thereof may be used in combination.

When in the reaction between the component (A′) and the component (a3), for example, the amount of the reacting component (a3) is 0.1 to 1.0 equivalents relative to 1 equivalent of hydroxy group of the component (A′), the acid value of the acid-modified (meth)acryloyl group-containing epoxy resin derivative can be adjusted.

The content of the component (A) in the photosensitive resin composition of the embodiment is not particularly limited, but from the viewpoint of resolution and dielectric properties, it is preferably 10 to 80% by mass, more preferably 20 to 60% by mass, and still more preferably 30 to 50% by mass, relative to the whole amount of a resin component of the photosensitive resin composition.

In the description, the “resin component” means a resin and a compound forming a resin by a curing reaction. In the resin composition of the embodiment, for example, the components (A) to (E) are classified as the resin component.

When the resin composition of the embodiment contains as an optional component the resin or the compound forming a resin by a curing reaction in addition to the components, the resin component includes the optional component. Examples of the optional component corresponding to the resin component include (G) a thiol compound, (H) an epoxy resin, (I) a curing accelerator for epoxy resin, and (J) a surface modifier as the other component.

In contrast, the resin component does not include (F) an inorganic filler or (J) a pigment, a flame retarder, or the like as the other component.

### <(B) (Meth)Acrylate Compound Having Two or More (Meth)Acryloyl Groups>

The photosensitive resin composition of the embodiment contains (B) the (meth)acrylate compound having two or more (meth)acryloyl groups.

Since the component (B) has a (meth)acryloyl group similarly to the component (A), the component (B) is a compound that undergoes a photo-radical polymerization reaction.

The component (B) is mainly used as a cross-linker for the component (A). Due to the component (B) contained in the photosensitive resin composition of the embodiment, the density of cross-linking formed by the photo-radical polymerization reaction tends to be increased, to improve resistance to alkaline developer, resolution, heat resistance, and weather resistance.

One type of the component (B) may be used alone, or two or more types thereof may be used in combination.

The number of (meth)acryloyl groups of the component (B) is 2 or more, and from the viewpoint of resolution, heat resistance, and dielectric properties, it is preferably 2 to 10, more preferably 2 to 8, and still more preferably 2 to 7.

The component (B) may have a functional group other than the (meth)acryloyl group, but it is preferable that the component (B) do not have an acidic substituent such as a carboxy group, a sulfonic acid group, and a phenolic hydroxy group.

Examples of the component (B) include bifunctional (meth)acrylate compounds including aliphatic di(meth)acrylates trimethylolpropane di(meth)acrylate, polypropylene glycol di(meth)acrylate, and polyethylene glycol di(meth)acrylate; di(meth)acrylates having an alicyclic skeleton, such as dicyclopentadiene di(meth)acrylate and tricyclodecanedimethanol di(meth)acrylate; and aromatic di(meth)acrylates such as 2,2-bis(4-(meth)acryloxypolyethoxypolypropoxyphenyl) propane and bisphenol A diglycidyl ether di(meth)acrylate; tri- or polyfunctional (meth)acrylate compounds including (meth)acrylate compounds having a trimethylolpropane-derived skeleton, such as trimethylolpropane tri(meth)acrylate; (meth)acrylate compounds having a tetramethylolmethane-derived skeleton, such as tetramethylolmethane tri(meth)acrylate and tetramethylolmethane tetra(meth)acrylate; (meth)acrylate compounds having a pentaerythritol-derived skeleton, such as pentaerythritol tri(meth)acrylate and pentaerythritol tetra(meth)acrylate; (meth)acrylate compounds having a dipentaerythritol-derived skeleton, such as dipentaerythritol penta(meth)acrylate and dipentaerythritol hexa(meth)acrylate; (meth)acrylate compounds having a ditrimethylolpropane-derived skeleton, such as ditrimethylolpropane tetra(meth)acrylate; and (meth)acrylate compounds having a diglycerol-derived skeleton; and (meth)acrylate compounds having an isocyanuric acid-derived skeleton, such as isocyanuric acid EO-modified diacrylate and triacrylate and ε-caprolactone-modified tris(acryloxyethyl) isocyanurate.

Here, the “(meth)acrylate compound having a XXX-derived skeleton” (“XXX” is a compound name) means an esterified product between XXX and (meth)acrylic acid, and the esterified product also includes a compound modified with an alkyleneoxy group.

Of these, from the viewpoint of resolution, heat resistance, and dielectric properties, the component (B) is preferably a (meth)acrylate compound having a trimethylolpropane-derived skeleton (hereinafter also referred to as “component (B1)”) or a (meth)acrylate compound having a dipentaerythritol-derived skeleton (hereinafter also referred to as “component (B2)”, and more preferably a combination thereof.

When the component (B) contains the component (B1) and the component (B2), the ratio on a mass basis of the contents of the components (component (B1): component (B2)) is preferably 1:99 to 40:60, more preferably 3:97 to 20:80, and still more preferably 5:95 to 15:85.

The component (B1) is preferably trimethylolpropane tri(meth)acrylate. The component (B2) is preferably dipentaerythritol hexa(meth)acrylate.

The content of the component (B) in the photosensitive resin composition of the embodiment is not particularly limited, but from the viewpoint of resolution, heat resistance, and dielectric properties, it is preferably 10 to 80 parts by mass, more preferably 20 to 60 parts by mass, and still more preferably 30 to 50 parts by mass, relative to 100 parts by mass of the component (A).

<(C) Compound Having Two or More Ethylenically Unsaturated Groups Other than (Meth)Acryloyl Groups>

The photosensitive resin composition of the embodiment contains (C) the compound having two or more ethylenically unsaturated groups other than the (meth)acryloyl groups.

The component (C) is a compound that undergoes a thermal radical polymerization reaction using (E) the organic peroxide below as a polymerization initiator, and mainly contributes to improvement of the heat resistance of a cured product of the photosensitive resin composition of the embodiment. Since the component (C) can be cured without generating a hydroxy group unlike an epoxy resin, the photosensitive resin composition of the embodiment containing the component (C) tends to have an excellent dielectric dissipation factor (Df).

One type of the component (C) may be used alone, or two or more types thereof may be used in combination.

In the description, the “ethylenically unsaturated group” means a substituent having an ethylenically unsaturated bond. The “ethylenically unsaturated bond” means a carbon-carbon double bond capable of an addition reaction, and does not include a double bond of an aromatic ring.

Examples of the ethylenically unsaturated group other than the (meth)acryloyl group include a maleimide group, a nadimide group, an allyl group, a vinyl group, a propargyl group, a butenyl group, an ethynyl group, and a phenylethynyl group. Of these, one or more selected from the group consisting of a maleimide group, an allyl group, a nadimide group, and vinyl group are preferred.

The component (C) may have a functional group other than the ethylenically unsaturated group, but it is preferable that the component (C) do not have an acidic substituent such as a carboxy group, a sulfonic acid group, and a phenolic hydroxy group; or a (meth)acryloyl group.

The component (C) is preferably one or more selected from the group consisting of a compound having two or more maleimide groups (hereinafter also referred to as “polyfunctional maleimide compound (C1)”), a compound having two or more allyl groups (hereinafter also referred to as “polyfunctional allyl compound (C2)”), a compound having two or more nadimide groups (hereinafter also referred to as “polyfunctional nadimide compound (C3)”), and a compound having two or more vinyl groups (hereinafter also referred to as “polyfunctional vinyl compound (C4)”).

Hereinafter, the components will be described in turn.

### ((C1) Polyfunctional Maleimide Compound)

The number of maleimide groups of the polyfunctional maleimide compound (C1) is 2 or more, and from the viewpoint of heat resistance and handleability, it is preferably 2 to 6, more preferably 2 to 5, and still more preferably 2 to 4.

Examples of the polyfunctional maleimide compound (C1) include an aromatic maleimide compound and an aliphatic maleimide compound. Of these, from the viewpoint of heat resistance and handleability, an aromatic maleimide compound is preferred. In the description, the “aromatic maleimide compound” means a compound having a N-substituted maleimide group that is directly bonded to an aromatic ring. The “aliphatic maleimide compound” means a compound having a N-substituted maleimide group that is directly bonded to an aliphatic hydrocarbon.

Examples of the aromatic maleimide compound include N,N′-ethylenebismaleimide, N,N′-hexamethylenebismaleimide, N,N′-(1,3-phenylene)bismaleimide, N,N′-[1,3-(2-methylphenylene)]bismaleimide, N,N′-[1,3-(4-methylphenylene)]bismaleimide, N,N′-(1,4-phenylene)bismaleimide, bis(4-maleimidophenyl) methane, bis(3-methyl-4-maleimidophenyl) methane, 3,3′-dimethyl-5,5′-diethyl-4,4′-diphenylmethanebismaleimide, bis(4-maleimidophenyl) ether, bis(4-maleimidophenyl) sulfone, bis(4-maleimidophenyl) sulfide, bis(4-maleimidophenyl) ketone, bis(4-maleimidocyclohexyl) methane, 1,4-bis(4-maleimidophenyl)cyclohexane, 1,4-bis(maleimidomethyl) cyclohexane, 1,4-bis(maleimidomethyl) benzene, 1,3-bis(4-maleimidophenoxy)benzene, 1,3-bis(3-maleimidophenoxy)benzene, bis[4-(3-maleimidophenoxy)phenyl]methane, bis [4-(4-maleimidophenoxy)phenyl]methane, 1,1-bis[4-(3-maleimidophenoxy)phenyl]ethane, 1,1-bis[4-(4-maleimidophenoxy)phenyl]ethane, 1,2-bis[4-(3-maleimidophenoxy)phenyl]ethane, 1,2-bis[4-(4-maleimidophenoxy)phenyl]ethane, 2,2-bis[4-(3-maleimidophenoxy)phenyl]propane, 2,2-bis[4-(4-maleimidophenoxy)phenyl]propane, 2,2-bis[4-(3-maleimidophenoxy)phenyl]butane, 2,2-bis[4-(4-maleimidophenoxy)phenyl]butane, 2,2-bis[4-(3-maleimidophenoxy)phenyl]-1,1,1,3,3,3-hexafluoropropane, 2,2-bis[4-(4-maleimidophenoxy)phenyl]-1,1,1,3,3,3-hexafluoropropane, 4,4-bis(3-maleimidophenoxy) biphenyl, 4,4-bis(4-maleimidophenoxy) biphenyl, bis[4-(3-maleimidophenoxy)phenyl]ketone, bis[4-(4-maleimidophenoxy)phenyl]ketone, bis(4-maleimidophenyl)disulfide, bis[4-(3-maleimidophenoxy)phenyl]sulfide, bis[4-(4-maleimidophenoxy)phenyl]sulfide, bis[4-(3-maleimidophenoxy)phenyl]sulfoxide, bis[4-(4-maleimidophenoxy)phenyl]sulfoxide, bis[4-(3-maleimidophenoxy)phenyl]sulfone, bis[4-(4-maleimidophenoxy)phenyl]sulfone, bis[4-(3-maleimidophenoxy)phenyl]ether, bis[4-(4-maleimidophenoxy)phenyl]ether, 1,4-bis[4-(4-maleimidophenoxy)-α,α-dimethylbenzyl]benzene, 1,3-bis[4-(4-maleimidophenoxy)-α,α-dimethylbenzyl]benzene, 1,4-bis[4-(3-maleimidophenoxy)-α,α-dimethylbenzyl]benzene, 1,3-bis[4-(3-maleimidophenoxy)-α,α-dimethylbenzyl]benzene, 1,4-bis[4-(4-maleimidophenoxy)-3,5-dimethyl-α,α-dimethylbenzyl]benzene, 1,3-bis[4-(4-maleimidophenoxy)-3,5-dimethyl-α,α-dimethylbenzyl]benzene, 1,4-bis[4-(3-maleimidophenoxy)-3,5-dimethyl-α,α-dimethylbenzyl]benzene, 1,3-bis[4-(3-maleimidophenoxy)-3,5-dimethyl-α,α-dimethylbenzyl]benzene, polyphenylmethanemaleimide, and a biphenyl aralkyl type maleimide resin. Of these, a biphenyl aralkyl type maleimide resin is preferred.

### ((C2) Polyfunctional Allyl Compound)

The number of allyl groups of the polyfunctional allyl compound (C2) is 2 or more, and from the viewpoint of heat resistance and handleability, it is preferably 2 to 6, more preferably 2 to 5, and still more preferably 2 to 4.

The polyfunctional allyl compound (C2) is preferably a polyfunctional allyl compound having a heterocyclic ring.

Examples of the polyfunctional allyl compound having a heterocyclic ring include allyl group-containing isocyanurates such as diallyl isocyanurate and triallyl isocyanurate; allyl group-containing cyanurates such as diallyl cyanurate and triallyl cyanurate; and 1,3,4,6-tetraallyl glycoluril. Of these, from the viewpoint of heat resistance, dielectric properties, and handleability, allyl group-containing isocyanurates are preferred, and diallyl isocyanurate is more preferred.

Examples of an allyl compound other than the polyfunctional allyl compound having a heterocyclic ring include allyl ether compounds such as trimethylolpropane triallyl ether, pentaerythritol diallyl ether, pentaerythritol triallyl ether, pentaerythritol tetraallyl ether, bisphenol A diallyl ether, bisphenol F diallyl ether, propylene glycol diallyl ether, glycerol diallyl ether, and poly(oxypropylene) diallyl ether; and allyl ester compounds such as diallyl phthalate, ethylene glycol bisallyl carbonate, diallyl naphthalate, and triallyl trimellitate.

### ((C3) Polyfunctional Nadimide Compound)

The polyfunctional nadimide compound (C3) is preferably a bisallyl nadimide compound represented by the following general formula (C-1).

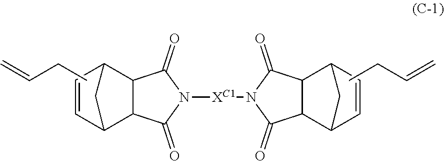

In the formula, X^{C1} represents a divalent organic group having 1 to 20 carbon atoms.

Examples of the divalent organic group having 1 to 20 carbon atoms represented by X^{C1} include an alkylene group, an alkenylene group, an alkynylene group, and arylene group, and a divalent connecting group in which they are combined.

Examples of the alkylene group include a methylene group, a 1,2-dimethylene group, a 1,3-trimethylene group, a 1,4-tetramethylene group, and a 1,5-pentamethylene group.

Examples of the alkenylene group include a vinylene group, a propenylene group, and a butenylene group.

Examples of the alkynylene group include an ethynylene group and a propynylene group.

Examples of the arylene group include a phenylene group and a naphthylene group.

Of these, X^{C1} is preferably the alkylene group or the arylene group.

The number of carbon atoms of the divalent organic group having 1 to 20 carbon atoms represented by X^{C1} is preferably 2 to 18, more preferably 4 to 16, and still more preferably 6 to 14.

From the viewpoint of dielectric properties, X^{C1} is preferably a divalent organic group represented by the following general formula (C-2) or a divalent organic group represented by the following general formula (C-3), and more preferably the divalent organic group represented by the following general formula (C-3).

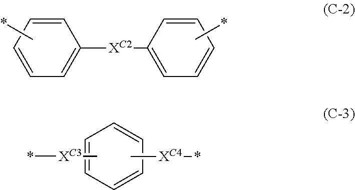

X^{C2}, X^{C3}, and X^{C4} are each independently an alkylene group having 1 to 10 carbon atoms, and * represents a binding site.

Examples of the alkylene group having 1 to 10 carbon atoms represented by X^{C2}, X^{C3}, and X^{C4} include the same groups as those exemplified in the description of X^{C1}. Of these, a methylene group is preferred.

The number of carbon atoms of the alkylene group having 1 to 10 carbon atoms represented by X^{C2}, X^{C3}, and X^{C4} is preferably 1 to 5, more preferably 1 to 3, still more preferably 1 or 2, and particularly preferably 1.

### ((C4) Polyfunctional Vinyl Compound)

Examples of the polyfunctional vinyl compound (C4) include compounds having a vinyl group that is directly bonded to an aromatic ring, such as m-divinylbenzene, p-divinylbenzene, 1,2-diisopropenylbenzene, 1,3-diisopropenylbenzene, 1,4-diisopropenylbenzene, 1,3-divinylnaphthalene, 1,8-divinylnaphthalene, 1,4-divinylnaphthalene, 1,5-divinylnaphthalene, 2,3-divinylnaphthalene, 2,7-divinylnaphthalene, 2,6-divinylnaphthalene, 4,4′-divinylbiphenyl, 4,3′-divinylbiphenyl, 4,2′-divinylbiphenyl, 3,2′-divinylbiphenyl, 3,3′-divinylbiphenyl, 2,2′-divinylbiphenyl, 2,4-divinylbiphenyl, 1,2-divinyl-3,4-dimethylbenzene, 2,2′-divinyl-4-ethyl-4′-propylbiphenyl; vinyl ether compounds such as 1,4-butanediol divinyl ether, cyclohexanedimethanol divinyl ether, and diethylene glycol divinyl ether; and polymers having a vinyl group such as a polybutadiene-based elastomer having a 1,2-vinyl group and a polyisoprene-based elastomer having a 1,2-vinyl group.

Of these, polymers having a vinyl group are preferred, and a polybutadiene-based elastomer having a 1,2-vinyl group is more preferred. A 1,2-vinyl group of the polybutadiene-based elastomer having a 1,2-vinyl group is a vinyl group contained in a butadiene-derived structural unit represented by the following formula (C-4).

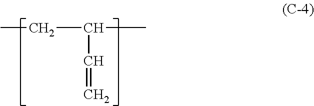

The polybutadiene-based elastomer having a 1,2-vinyl group may be a polybutadiene homopolymer having a 1,2-vinyl group or a copolymer of butadiene and a monomer other than butadiene. The copolymer of butadiene and a monomer other than butadiene is preferably a butadiene-styrene copolymer having a 1,2-vinyl group.

The content of a structural unit having a 1,2-vinyl group (hereinafter also referred to as “vinyl group content”) relative to the whole structural unit constituting the polybutadiene-based elastomer having a 1,2-vinyl group is not particularly limited, but is preferably 10 to 98% by mole, more preferably 20 to 95% by mole, and still more preferably 25 to 90% by mole.

The butadiene-styrene copolymer having a 1,2-vinyl group is available as a commercial product, and examples thereof include “Ricon (registered trademark) 100”, “Ricon (registered trademark) 181”, and “Ricon (registered trademark) 184” (trade name, all manufactured by Cray Valley).

From the viewpoint of resolution, the polybutadiene-based elastomer having a 1,2-vinyl group may have an acid anhydride group.

Examples of the acid anhydride group include acid anhydride groups derived from phthalic anhydride, maleic anhydride, trimellitic anhydride, pyromellitic anhydride, hexahydrophthalic anhydride, tetrahydrophthalic anhydride, methylnadic anhydride, nadic anhydride, glutaric anhydride, dimethylglutaric anhydride, diethylglutaric anhydride, succinic anhydride, methylhexahydrophthalic anhydride, and methyltetrahydrophthalic anhydride. An acid anhydride group derived from maleic anhydride is preferred.

When the polybutadiene-based elastomer having a 1,2-vinyl group has an acid anhydride group, from the viewpoint of resolution and dielectric properties, the number of acid anhydride groups in one molecule is preferably 1 to 12, more preferably 3 to 11, and still more preferably 6 to 10.

The poly butadiene-based elastomer having an acid anhydride group derived from maleic anhydride is available as a commercial product, and examples thereof include “POLYVEST (registered trademark) MA75” and “POLYVEST (registered trademark) EP MA120” (trade name, all manufactured by Evonik Industries AG.), and “Ricon (registered trademark) 130MA8”, “Ricon (registered trademark) 131MA5”, “Ricon (registered trademark) 131MA17”, and “Ricon (registered trademark) 184MA6” (trade name, all manufactured by Cray Valley).

The number average molecular weight of the poly butadiene-based elastomer having a 1,2-vinyl group is not particularly limited, but from the viewpoint of resolution, impact resistance, and heat resistance, it is preferably 1,000 to 10,000, more preferably 2,000 to 8,000, and still more preferably 3,000 to 6,000.

In the description, the number average molecular weight is a value determined in terms of standard polystyrene by gel permeation chromatography (GPC) using tetrahydrofuran as a solvent, and specifically, a value measured according to a method described in Examples.

The photosensitive resin composition of the embodiment preferably contains as the component (C) one or more selected from the group consisting of the component (C1), the component (C2), and the component (C3), and the component (C4), and more preferably contains one or more selected from the group consisting of the component (C1), the component (C2), and the component (C3), and the poly butadiene-based elastomer having a 1,2-vinyl group.

When the photosensitive resin composition of the embodiment contains one or more selected from the group consisting of the component (C1), the component (C2), and the component (C3), and the poly butadiene-based elastomer having a 1,2-vinyl group, from the viewpoint of resolution, heat resistance, and dielectric properties, the content ratio on a mass basis (one or more selected from the group consisting of the component (C1), the component (C2), and the component (C3): the poly butadiene-based elastomer having a 1,2-vinyl group) is preferably 40:60 to 95:5, more preferably 50:50 to 90:10, and still more preferably 60:40 to 85:15.

The content of the component (C) in the photosensitive resin composition of the embodiment is not particularly limited, but from the viewpoint of heat resistance and dielectric properties, it is preferably 1 to 80% by mass, more preferably 3 to 60% by mass, and still more preferably 6 to 50% by mass, relative to the whole amount of the resin component of the photosensitive resin composition.

### <(D) Photopolymerization Initiator>

The photopolymerization initiator (D) is a polymerization initiator for the photo-radical polymerization reaction of the (meth)acryloyl group which the component (A) and the component (B) mainly have.

Due to the photopolymerization initiator (D) contained in the photosensitive resin composition of the embodiment, the photo-radical polymerization reaction of the component (A) and the component (B) tends to be promoted, to improve resolution, heat resistance, and dielectric properties.

One type of the photopolymerization initiator (D) may be used alone, or two or more types thereof may be used in combination.

The photopolymerization initiator (D) is not particularly limited as long as the (meth)acryloyl group can be photopolymerized, and the photopolymerization initiator (D) can be appropriately selected from typically used photopolymerization initiators.

Examples of the photopolymerization initiator (D) include benzoin-based compounds such as benzoin, benzoin methyl ether, and benzoin isopropyl ether; acetophenone-based compounds such as acetophenone, 2,2-dimethoxy-2-phenylacetophenone, 2,2-diethoxy-2-phenylacetophenone, 1,1-dichloroacetophenone, 1-hydroxycyclohexylphenyl ketone, 2-benzyl-2-dimethylamino-1-(4-morpholinophenyl)-1-butanone, 2-[4-(methylthio)benzoyl]-2-(4-morpholinyl) propane, and N,N-dimethylaminoacetophenone; anthraquinone-based compounds such as 2-methylanthraquinone, 2-ethylanthraquinone, 2-tert-butylanthraquinone, 1-chloroanthraquinone, 2-amylanthraquinone, and 2-aminoanthraquinone; ketal-based compounds such as acetophenone dimethyl ketal and benzyl dimethyl ketal; acridine-based compounds such as 9-phenylacridine and 1,7-bis(9,9′-acridinyl) heptane; acylphosphine oxide-based compounds such as bis(2,4,6-trimethylbenzoyl)phenylphosphine oxide; oxime ester-based compounds such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(O-acetyloxime), and 1-phenyl-1,2,-propanedione-2-[O-(ethoxy carbonyl) oxime]; thioxanthone-based compounds such as 2,4-dimethylthioxanthone, 2,4-diethylthioxanthone, 2-chlorothioxanthone, and 2,4,-diisopropylthioxanthone; and benzophenone-based compounds such as 4,4′-bis(dimethylamino) benzophenone and 4,4′-bis(diethylamino) benzophenone.

Of these, acetophenone-based compounds, thioxanthone-based compounds, and benzophenone-based compounds are preferred, and from the viewpoint of improving sensitivity and enhancing curing properties of a deep portion, a combination of acetophenone-based compounds, thioxanthone-based compounds, and benzophenone-based compounds are more preferred.

The content of the acetophenone-based compound in the photopolymerization initiator (D) is preferably 50 to 98% by mass, more preferably 70 to 95% by mass, and still more preferably 80 to 90% by mass.

The content of the thioxanthone-based compound or the benzophenone-based compound in the photopolymerization initiator (D) is preferably 1 to 20% by mass, more preferably 2 to 15% by mass, and still more preferably 4 to 10% by mass.

The acetophenone-based compound is preferably 2-[4-(methylthio)benzoyl]-2-(4-morpholinyl) propane. The thioxanthone-based compound is preferably 2,4-dimethylthioxanthone. The benzophenone-based compound is preferably 4,4′-bis(dimethylamino) benzophenone.

The content of the photopolymerization initiator (D) in the photosensitive resin composition of the embodiment is not particularly limited, but from the viewpoint of homogeneously and sufficiently promoting the photo-radical polymerization reaction, it is preferably 0.1 to 20 parts by mass, more preferably 1 to 10 parts by mass, and still more preferably 2 to 4 parts by mass, relative to 100 parts by mass of the total amount of the component (A) and the component (B).

### <(E) Organic Peroxide>

The organic peroxide (E) is a polymerization initiator for a thermal radical polymerization reaction of the ethylenically unsaturated group which the component (C) mainly has.

Due to the organic peroxide (E) contained in the photosensitive resin composition of the embodiment, the thermal radical polymerization reaction of the component (C) tends to be promoted, to improve heat resistance and dielectric properties.

The organic peroxide (E) is not particularly limited as long as it is an organic compound having a peroxide bond (—O—O—).

One type of the organic peroxide (E) may be used alone, or two or more types thereof may be used in combination.

The one-hour half-life temperature of the organic peroxide (E) is not particularly limited, but from the viewpoint of suppressing an unintended reaction before and during development and then promoting the thermal radical polymerization reaction under proper heating, it is preferably 100 to 200° C., more preferably 120 to 170° C., and still more preferably 130 to 150° C.

The one-hour half-life temperature of the organic peroxide (E) can be determined by determining the decomposition rate constant at each temperature at which the organic peroxide (E) in a solvent is subjected to a decomposition reaction under a plurality of temperature conditions, and then making an Arrhenius plot of the decomposition rate constant thereof. Here, the one-hour half-life temperature of the embodiment is one-hour half-life temperature measured under a condition in which the concentration of the organic peroxide (E) in benzene is 0.1 mol/L.

Examples of the organic peroxide (E) include peroxy ketals such as 1,1-di(t-butyl peroxy)cyclohexane, 2,2-di(t-butyl peroxy) butane, 2,2-di(4,4-di-t-butyl peroxycyclohexyl) propane, and 1,1-di(t-amyl peroxy)cyclohexane: hydroperoxides such as cumene hydroperoxide and t-butyl hydroperoxide: alkyl peroxides such as t-butyl peroxyacetate and t-amyl peroxyisononanoate: dialkyl peroxides such as t-butyl cumyl peroxide, di-t-butyl peroxide, dicumyl peroxide, di-t-hexyl peroxide, and 1,3-bis(2-t-butyl peroxyisopropyl)benzene: peroxy esters such as t-butyl peroxyacetate, t-butyl peroxy benzoate, and t-butyl peroxyisopropyl monocarbonate: peroxy carbonates such as t-butyl peroxyisopropyl carbonate and polyether tetrakis(t-butyl peroxy carbonate); and diacyl peroxides such as dibenzoyl peroxide. Of these, 1,3-bis(2-t-butyl peroxyisopropyl)benzene is preferred.

The content of the organic peroxide (E) in the photosensitive resin composition of the embodiment is not particularly limited, but from the viewpoint of homogeneously and sufficiently promoting the thermal radical polymerization reaction, it is preferably 0.1 to 20 parts by mass, more preferably 1 to 15 parts by mass, and still more preferably 2 to 12 parts by mass, relative to 100 parts by mass of the component (C).

### <(F) Inorganic Filler>

Further, the photosensitive resin composition of the embodiment preferably contains the inorganic filler (F).

Due to the inorganic filler (F) contained in the photosensitive resin composition of the embodiment, heat resistance, flame retardant, and low thermal expansibility tend to be improved.

One type of the inorganic filler (F) may be used alone, or two or more types thereof may be used in combination.

Examples of the inorganic filler (F) include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, yttria-containing zirconia, barium silicate, boron nitride, calcium carbonate, barium sulfate, calcium sulfate, zinc oxide, magnesium titanate, hydrotalcite, mica, firing kaolin, and carbon. Of these, from the viewpoint of heat resistance, flame retardant, and low thermal expansibility, silica is preferred. The inorganic filler (F) may be one surface-treated with a coupling agent such as a silane coupling agent.

From the viewpoint of resolution, the volume average particle diameter (D₅₀) of the inorganic filler (F) is preferably 0.01 to 5 μm, more preferably 0.1 to 1 μm, and still more preferably 0.3 to 0.7 μm.

The volume average particle diameter (D₅₀) of the inorganic filler (F) can be determined as particle diameter corresponding to a particle diameter at an integrated value of 50% (volume basis) in a particle size distribution obtained by measurement of particles dispersed in a solvent at a refractive index of 1.38 in accordance with International Standard ISO13321.

When the photosensitive resin composition of the embodiment contains the inorganic filler (F), the content of the inorganic filler (F) is not particularly limited, but from the viewpoint of heat resistance, flame retardant, low thermal expansibility, and resolution, it is preferably 10 to 70% by mass, more preferably 30 to 65% by mass, and still more preferably 40 to 60% by mass, relative to the whole amount of a solid content of the photosensitive resin composition.

In the description, the “solid content” means a nonvolatile substance contained in the photosensitive resin composition, exclusive of a volatile substance such as water and a solvent, and means a component that during drying the photosensitive resin composition, remains without being volatilized, and it also includes those that are in a liquid state, a starch syrup-like state, or a waxy state at room temperature in the vicinity of 25° C.

### <(G) Thiol Compound>

Further, the photosensitive resin composition of the embodiment preferably contains the thiol compound (G).

Due to the thiol compound (G) contained in the photosensitive resin composition of the embodiment, oxygen inhibition during photo-curing the photosensitive resin composition tends to be suppressed. Thus, even when a carrier film is peeled and the photosensitive resin composition of the embodiment is exposed to light under exposure to air, excellent surface curing properties are easily obtained. Therefore, scattering of light by the carrier film is suppressed, and excellent resolution is easily obtained.

One type of the thiol compound (G) may be used alone, or two or more types thereof may be used in combination.

The number of thiol groups of the thiol compound (G) is not particularly limited, but is preferably 2 or more, more preferably 2 to 8, and still more preferably 2 to 6.

Examples of the thiol compound (G) include 2-mercaptobenzothiazole, 1,4-bis(3-mercaptobutyryloxy) butane, 1,3,5-tris(3-mercaptobutyloxyethyl)-1,3,5-triazine-2,4,6 (1H,3H,5H)-trione, trimethylolpropane tris(3-mercaptopropionate), pentaerythritol tetrakis(3-mercaptobutyrate), pentaerythritol tetrakis(3-mercaptopropionate), dipentaerythritol hexakis (3-mercaptopropionate), tetraethylene glycol bis(3-mercaptopropionate), pentaerythrityl tetrathiol, and 2-ethyl-2-(sulfanylmethyl) propane-1,3-dithiol. Of these, pentaerythritol tetrakis(3-mercaptobutyrate) is preferred.

When the photosensitive resin composition of the embodiment contains the thiol compound (G), the content of the thiol compound (G) is not particularly limited, but from the viewpoint of surface curing properties, it is preferably 0.1 to 20% by mass, more preferably 0.5 to 15% by mass, and still more preferably 1 to 12% by mass, relative to the whole amount of the resin component of the photosensitive resin composition.

### <(H) Epoxy Resin>

The photosensitive resin composition of the embodiment may further contain the epoxy resin (H).

One type of the epoxy resin (H) may be used alone, or two or more types thereof may be used in combination.

The epoxy resin (H) is preferably an epoxy resin having two or more epoxy groups. The epoxy resin (H) is classified into a glycidyl ether type epoxy resin, a glycidyl amine type epoxy resin, a glycidyl ester type epoxy resin, and the like. Of these, a glycidyl ether type epoxy resin is preferred.

The epoxy resin (H) is classified into various epoxy resins depending upon a difference of the main skeleton, and the epoxy resins of respective types are further classified as follows. Specifically, the epoxy resins are classified into a bisphenol-based epoxy resin such as a bisphenol A type epoxy resin, a bisphenol F type epoxy resin, or a bisphenol S type epoxy resin; a bisphenol novolak type epoxy resin such as a bisphenol A novolak type epoxy resin or a bisphenol F novolak type epoxy resin; a novolak type epoxy resin other than the bisphenol novolak type epoxy resin, such as a phenol novolak type epoxy resin, a cresol novolak type epoxy resin, or a biphenyl novolak type epoxy resin; a phenol aralkyl type epoxy resin; a stilbene type epoxy resin; a naphthalene skeleton-containing epoxy resin such as a naphthol novolac type epoxy resin, a naphthol type epoxy resin, a naphthol aralkyl type epoxy resin, or a naphthylene ether type epoxy resin; a biphenyl type epoxy resin; a biphenyl aralkyl type epoxy resin; a xylylene type epoxy resin; a dihydroanthracene type epoxy resin; an alicyclic epoxy resin such as a saturated dicyclopentadiene type epoxy resin; an heterocyclic epoxy resin; a spiro ring-containing epoxy resin; a cyclohexane dimethanol type epoxy resin; a trimethylol type epoxy resin; an aliphatic linear epoxy resin; a rubber-modified epoxy resin; or the like. Of these, a naphthalene skeleton-containing epoxy resin and a biphenyl aralkyl type epoxy resin are preferred.

Whether the photosensitive resin composition of the embodiment contains the epoxy resin (H) and, when the photosensitive resin composition contains the epoxy resin, the content thereof may be appropriately determined according to desired characteristics.

For example, when the photosensitive resin composition of the embodiment contains the epoxy resin (H), from the viewpoint of heat resistance and adherence to copper wiring, the content of the epoxy resin (H) may be 1 to 50% by mass, 5 to 40% by mass, or 10 to 30% by mass, relative to the whole amount of the resin component of the photosensitive resin composition.

However, the photosensitive resin composition of the embodiment may be one not containing the epoxy resin (H) for a reduction in dielectric dissipation factor. When the photosensitive resin composition contains the epoxy resin (H), the content of the epoxy resin (H) may be 10% by mass or less, 5% by mass or less, or 1% by mass or less, relative to the whole amount of the resin component of the photosensitive resin composition.

### <(I) Curing Accelerator For Epoxy Resin>

When the photosensitive resin composition of the embodiment contains the epoxy resin (H), the photosensitive resin composition of the embodiment may further contain the curing accelerator for epoxy resin (I).

Due to the curing accelerator for epoxy resin (I) contained in the photosensitive resin composition of the embodiment, the curing properties of the epoxy resin (H) can be improved. One type of the curing accelerator for epoxy resin (I) may be used alone, or two or more types thereof may be used in combination.

Examples of the curing accelerator for epoxy resin (I) include imidazole-based compounds such as 2-methylimidazole, 2-ethyl-4-methylimidazole, 1-benzyl-2-methylimidazole, 2-phenylimidazole, 2-phenyl-1-benzyl-1H-imidazole, 2-phenyl-4-methyl-5-hydroxymethylimidazole, 1-(2-cyanoethyl)-2-ethyl-4-methylimidazole, and isocyanate-masked imidazole (an addition reaction product of a hexamethylene diisocyanate resin and 2-ethyl-4-methylimidazole): tertiary amines such as trimethylamine, N,N-dimethyloctylamine, N-benzyldimethylamine, pyridine, N-methylmorpholine, hexa (N-methyl) melamine, 2,4,6-tris(dimethylaminophenol), tetramethylguanidine, and m-aminophenol; organic phosphines such as tributylphosphine, triphenylphosphine, and tris-2-cyanoethylphosphine: phosphonium salts such as tri-n-butyl(2,5-dihydroxyphenyl)phosphonium bromide and hexadecyltributylphosphonium chloride: quaternary ammonium salts such as benzyltrimethylammonium chloride and phenyltributylammonium chloride: the aforementioned poly basic acid anhydrides; diphenyliodonium tetrafluoroborate, triphenylsulfonium hexafluoroantimonate, and 2,4,6-triphenylthiopyry lium hexafluorophosphate. Of these, from the viewpoint of curing properties, imidazole-based compounds are preferred, and 2-phenyl-1-benzyl-1H-imidazole is more preferred.

When the photosensitive resin composition of the embodiment contains the curing accelerator for epoxy resin (I), the content of the curing accelerator for epoxy resin (I) is not particularly limited, but from the viewpoint of homogeneously and sufficiently promoting a thermal curing reaction, it is preferably 0.1 to 10 parts by mass, more preferably 1 to 7 parts by mass, and still more preferably 2 to 4 parts by mass, relative to 100 parts by mass of the epoxy resin (H).

In contrast, when the photosensitive resin composition of the embodiment does not contain the epoxy resin (H), or the like, the photosensitive resin composition may be one not containing the curing accelerator for epoxy resin (I).

### <(J) Other Component>

The photosensitive resin composition of the embodiment may contain a component other than the aforementioned components as the other component (J), if necessary.

Examples of the other component (J) include a resin other than the aforementioned components: an organic filler: a curing agent for epoxy resin: pigments such as phthalocyanine blue, phthalocyanine green, iodine green, diazo yellow; crystal violet, titanium oxide, carbon black, and naphthalene black: adhesion aids such as melamine: foam stabilizers such as a silicone compound: a polymerization inhibitor; a thickener; and a flame retardant.

One type of each of these may be used alone, or two or more types thereof may be used in combination.

The content of the other component (J) may be appropriately adjusted according to the purpose thereof, but it may be 0.01 to 10% by mass, 0.05 to 5% by mass, or 0.1 to 1% by mass, relative to the whole amount of the resin component of the photosensitive resin composition.

The photosensitive resin composition of the embodiment may contain a diluent, if necessary.

As the diluent, an organic solvent, or the like can be used. Examples of the organic solvent include ketones such as methyl ethyl ketone and cyclohexanone: aromatic hydrocarbons such as toluene, xylene, and tetramethylbenzene; glycol ether-based compounds such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, propylene glycol monoethyl ether acetate, butyl cellosolve acetate, and carbitol acetate: aliphatic hydrocarbons such as octane and decane; and petroleum-based solvents such as petroleum ether, petroleum naphtha, hydrogenated petroleum naphtha, and solvent naphtha. One type of the diluent may be used alone, or two or more types thereof may be used in combination.

When the photosensitive resin composition of the embodiment contains the diluent, the concentration of the whole amount of the solid content in the photosensitive resin composition is preferably 40 to 90% by mass, more preferably 50 to 85% by mass, and still more preferably 60 to 80% by mass.

The relative dielectric constant (Dk) at a frequency of 10 GHz of a cured product of the photosensitive resin composition of the embodiment is not particularly limited, but from the viewpoint of low transmission loss, it is preferably 3.2 or less, more preferably 3.0 or less, and still more preferably 2.9 or less. A lower relative dielectric constant (Dk) of the cured product is favorable. The lower limit value thereof is not particularly limited, and may be, for example, 2.3 or more, 2.4 or more, or 2.5 or more in consideration of a balance between the relative dielectric constant and other physical properties.

A condition where a cured product is obtained from the resin composition of the embodiment can be a condition described in Examples.

The dielectric dissipation factor (Df) can be measured by a method described in Examples.

The dielectric dissipation factor (Df) at a frequency of 10 GHz of a cured product of the photosensitive resin composition of the embodiment is not particularly limited, but from the viewpoint of low transmission loss, it is preferably 0.0100 or less, more preferably 0.0090 or less, still more preferably 0.0080 or less, and particularly preferably 0.0070 or less. A lower dielectric dissipation factor (Df) of the cured product is favorable. The lower limit value thereof is not particularly limited, and may be, for example, 0.0040 or more, 0.0045 or more, or 0.0050 or more in consideration of a balance between the dielectric dissipation factor and other physical properties.

The condition where a cured product is obtained from the resin composition of the embodiment can be the condition described in Examples.

The dielectric dissipation factor (Df) can be measured by the method described in Examples.

The photosensitive resin composition of the embodiment can be produced by mixing the aforementioned components. In the mixing, for example, a roll mill, a bead mill, a planetary mixer, a planetary centrifugal mixer, or the like can be used.

The photosensitive resin composition of the embodiment is suited for via formation by a photolithography method. Therefore, the photosensitive resin composition of the embodiment is suitable for use as a photosensitive resin composition for photo via formation. The photosensitive resin composition of the embodiment is suitable as a negative photosensitive resin composition.

### [Photosensitive Resin Film]

A photosensitive resin film of the embodiment is a photosensitive resin film formed using the photosensitive resin composition of the embodiment.

Since the photosensitive resin film of the embodiment is excellent in dielectric properties, it is suited for formation of an interlayer insulating layer of a multilayered printed wiring board.

The photosensitive resin film of the embodiment may have a carrier film on a surface, and further have a protective film on the other surface.

Examples of a material for the carrier film include polyesters such as polyethylene terephthalate and polybutylene terephthalate; and polyolefins such as polypropylene and polyethylene. The thickness of the carrier film is preferably 5 to 100 μm, more preferably 10 to 60 μm, and still more preferably 15 to 45 μm.

Examples of the protective film include films of the same materials as those for the carrier film.

The photosensitive resin film of the embodiment can be produced, for example, by applying the photosensitive resin composition of the embodiment to the carrier film, and if necessary, drying it.

Examples of a coating device include a comma coater, a bar coater, a kiss coater, a roll coater, a gravure coater, and a die coater.

The drying temperature during drying a coated film formed by applying the photosensitive resin composition is preferably 60 to 150° C., more preferably 70 to 120° C., and still more preferably 80 to 100° C. The drying time is preferably 1 to 60 minutes, more preferably 2 to 30 minutes, and still more preferably 5 to 20 minutes.

The thickness of the photosensitive resin film is not particularly limited, but from the viewpoint of handleability and thinning of a multilayered printed wiring board, it is preferably 1 to 100 μm, more preferably 3 to 50 μm, and still more preferably 5 to 40 μm.

### [Multilayered Printed Wiring Board and Method for Producing Same]

A multilayered printed wiring board of the embodiment is one containing an interlayer insulating layer formed using the photosensitive resin composition or the photosensitive resin film of the embodiment.

The “interlayer insulating layer” contained in the multilayered printed wiring board of the embodiment includes, for example, one after various types of processing or treatment, such as formation of via and wiring and a roughening treatment.

A method for producing a multilayered printed wiring board of the embodiment is not particularly limited as long as it is a method using the photosensitive resin composition or the photosensitive resin film of the embodiment, but the method for producing a multilayered printed wiring board of the embodiment described below is preferred.

The method for producing a multilayered printed wiring board of the embodiment is a method for producing a multilayered printed wiring board including the following (1) to (4):
(1): laminating the photosensitive resin film of the embodiment on a surface or both surfaces of a circuit substrate (hereinafter also referred to as “laminating step (1)”):
(2): exposing and developing the photosensitive resin film laminated in (1), to form an interlayer insulating layer having a via (hereinafter also referred to as “photo via forming step (2)”):
(3): heating and curing the interlayer insulating layer having a via (hereinafter also referred to as “heating treatment step (3)”); and
(4): forming a circuit pattern on the interlayer insulating layer (hereinafter also referred to as “circuit pattern forming step (4)”).

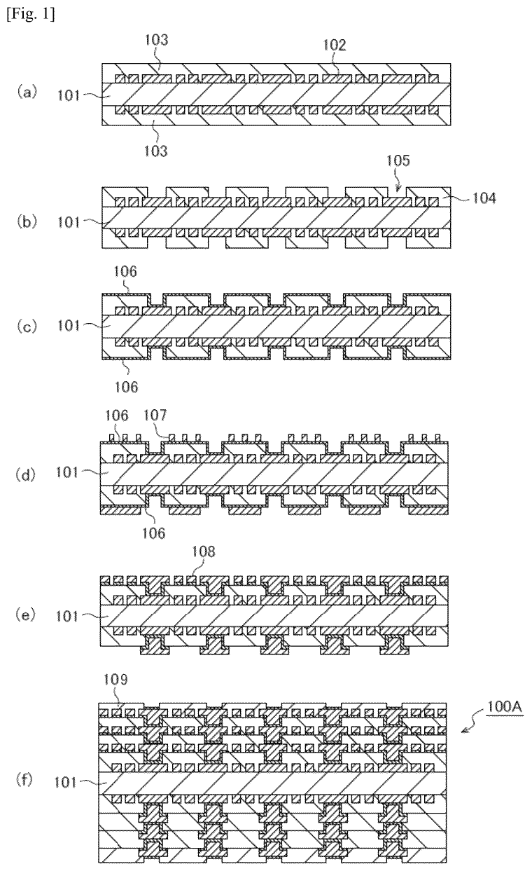

Hereinafter, the method for producing a multilayered printed wiring board of the embodiment will be described as appropriate with reference to FIG. 1.

In the description, for the sake of convenience, a predetermined operation may be referred to as “XX step”, but the “XX step” is not limited to an aspect alone specifically in the description.

### (Laminating Step (1))

In the laminating step (1), the photosensitive resin film of the embodiment is laminated on a surface or both surfaces of a circuit substrate.

FIG. 1 (a) illustrates a step of forming a photosensitive layer 103 on both surfaces of a substrate 101 having a circuit pattern 102.

The photosensitive layer 103 can be formed by laminating the photosensitive resin film of the embodiment on the surfaces of the substrate 101.

When the photosensitive resin film has a protective film, the laminating may be performed by removing the protective film and then pressure-bonding the photosensitive resin film to the substrate 101 under pressurizing or heating using a vacuum laminator or the like.

The laminating can be performed under a lamination condition of, for example, a pressure-bonding temperature of 70 to 130° C., a pressure-bonding pressure of 0.1 to 1.0 MPa, and a reduced pressure that is an air pressure of 20 mm Hg (26.7 hPa) or less.

A laminating method may be in a batch mode or a continuous mode with rolls.

When after the laminating, a carrier film is attached to the photosensitive layer 103, the carrier film may be peeled before exposure to light described below or may be peeled after the exposure to light.

### (Photo Via Forming Step (2))

In the photo via forming step (2), the photosensitive layer formed in the laminating step (1) is exposed and developed to form an interlayer insulating layer having a via.

FIG. 1 (b) illustrates a step of exposing and developing the photosensitive layer 103 to form an interlayer insulating layer 104 having a via 105.

When the photosensitive layer 103 is exposed, a photo-radical polymerization reaction is initiated by the photopolymerization initiator (D) contained in the photosensitive resin composition of the embodiment, to cure the component (A) and the component (B).

A method for exposing the photosensitive layer 103 may be, for example, a mask exposure method by imagewise irradiation with active light through a negative or positive mask pattern that is called an artwork, or a method by imagewise irradiation with active light by a direct imaging exposure method such as a laser direct imaging (LDI) exposure method or a digital light processing (DLP) exposure method.

Examples of an active light source include gas lasers such as a carbon arc lamp, a mercury vapor arc lamp, a high-pressure mercury lamp, a xenon lamp, and an argon laser; a solid state laser such as a YAG laser; and publicly known light sources such as one effectively radiating a ultraviolet ray or a visible ray, such as a semiconductor laser.

The exposure dose may be appropriately adjusted according to the used light source, the thickness of the photosensitive layer, and the like. When for example, the photosensitive layer having a thickness of 1 to 100 μm is exposed by irradiation with ultraviolet light from a high-pressure mercury lamp, the exposure dose is preferably 10 to 1,000 mJ/cm², more preferably 50 to 700 mJ/cm², and still more preferably 150 to 400 mJ/cm².

Subsequently, when the carrier film is present on the photosensitive layer 103, the carrier film is removed, followed by development. In the development, an uncured portion of the photosensitive layer 103 is removed, to form a photo-cured portion as the interlayer insulating layer 104 on the substrate.

A development method may be wet development or dry development, but wet development is preferred. Examples of a method by wet development include methods by a dipping process, a puddle process, a spraying process, brushing, slapping, scrapping, and swing immersion. Of these, from the viewpoint of improving the resolution, a spraying process is preferred.

Examples of a developer include an aqueous alkaline solution, an aqueous developer, and an organic solvent-based developer, and of these, an aqueous alkaline solution is preferred.

After the exposure and the development, from the viewpoint of increasing the curing degree of the interlayer insulating layer, post-exposure may be performed. The exposure dose in the post-exposure is preferably 0.2 to 10 J/cm², and more preferably 0.5 to 5 J/cm².

The shape of the via is not particularly limited. As it is described in terms of a cross-sectional shape, examples thereof include a rectangle and a reverse trapezoid (the top side is longer than the bottom side). The reverse trapezoid is a shape in which the top side is longer than the bottom side. As the shape of the via is described as viewed in plan view (in a direction in which the via bottom is seen), examples thereof include a circle and a rectangle.

In formation of the via by a photolithography method of the embodiment, a via having a cross-sectional shape of a reverse trapezoid can be formed. The via having the aforementioned shape is preferred since a throwing power on a via wall surface of copper plating is high.

In the formation of the via by the photolithography method of the embodiment, the diameter of the via can be made smaller than the diameter of a via produced by laser processing. The diameter of the via formed by the production method of the embodiment may be, for example, 40 μm or less, 35 μm or less, or 30 μm or less. The lower limit value of the diameter of the via is not particularly limited, but, for example, it may be 15 μm or more or 20 μm or more.

### (Heating Treatment Step (3))

In the heating treatment step (3), the interlayer insulating layer having the via is heated and cured.

Specifically, in the heating treatment step (3), the thermal radical polymerization reaction of the component (C) by the organic peroxide (E) contained in the photosensitive resin composition of the embodiment, and when the epoxy resin (H) and the curing accelerator for epoxy resin (I) are contained, an epoxy polymerization reaction of the component (H) by the curing accelerator for epoxy resin (I) are initiated, resulting in curing.

The heating temperature is not particularly limited, but is preferably 100 to 300° C., more preferably 120 to 200° C., and still more preferably 150 to 180° C. The heating time is not particularly limited, but is preferably 0.3 to 3 hours, more preferably 0.5 to 2 hours, and still more preferably 0.75 to 1.5 hours.

### (Circuit Pattern Forming Step (4))

In the circuit pattern forming step (4), a circuit pattern is formed on the interlayer insulating layer.

From the viewpoint of forming a micro wiring, the circuit pattern is preferably formed by a semi-additive process. According to the semi-additive process, conduction of the via is performed along with the formation of the circuit pattern. Specifically, the semi-additive process is preferably performed by performing a roughening treatment, formation of a seed layer, formation of a resist pattern, formation of a circuit layer of copper, and removal of the resist pattern, in this order.

### [Roughening Treatment]

The roughening treatment is a treatment of roughening the surface of the interlayer insulating layer to form irregular anchors. When a smear is generated in the photo via forming step (2), removal of the smear and the roughening treatment using a roughening liquid may be performed at the same time.

Examples of the roughening liquid include an alkaline permanganic acid roughening liquid such as a sodium permanganate roughening liquid: a chromium/sulfuric acid roughening liquid, and a sodium fluoride/chromium/sulfuric acid roughening liquid.

### [Formation of Seed Layer]

FIG. 1 (c) illustrates a step of forming a seed layer 106.

The seed layer 106 is one for forming a power supply layer for the purpose of performing copper electroplating.

The seed layer 106 can be formed by performing an electroless copper plating treatment of the via bottom, the via wall surface, and the entire surface of the interlayer insulating layer using a palladium catalyst or the like. The thickness of the seed layer 106 is not particularly limited, but may be, for example, 0.1 to 5 μm or 0.2 to 2 μm.

As an electroless plating method, a publicly known method can be used. As an electroless copper plating solution, a commercially available product can be used, and examples of the commercially available product include “MSK-DK” manufactured by Atotech Japan K.K.; and “THRU-CUP (registered trademark) PEA” Series manufactured by C.Uyemura & Co., Ltd.

### [Formation of Resist Pattern]

FIG. 1 (d) illustrates a step of forming a resist pattern 107 on the seed layer 106.

The resist pattern 107 can be formed, for example, by thermocompression-bonding a dry film resist on the seed layer 106 using a roll laminator, or the like, and exposing and developing it.

The thickness of the dry film resist is not particularly limited, but is preferably 3 to 50 μm, and more preferably 5 to 30 μm.

As the dry film resist, a commercially available product can be used, and examples of the commercially available product include “PHOTEC (registered trademark)” series manufactured by Showa Denko K.K.

The dry film resist may be exposed through a mask having a desired wiring pattern drawn therein. As an exposure method, a method used in formation of a via in a photosensitive resin film can be adopted. After the exposure, the dry film resist is developed with an aqueous alkaline solution, and an unexposed portion is removed to form the resist pattern 107. After that, if necessary, a plasma treatment for removing a development residue of the dry film resist may be performed.

### [Formation of Circuit Layer of Copper and Removal of Resist Pattern]

FIG. 1 (e) illustrates a step of forming a circuit layer of copper 108.

The circuit layer of copper 108 is preferably formed by copper electroplating.

As a copper electroplating solution used in the copper electroplating, a commercially available copper electroplating solution such as an copper electroplating solution containing copper sulfate can be used.

After the copper electroplating, the resist pattern 107 is removed with an aqueous alkaline solution or an amine-based release agent, and flash etching of removing the seed layer 106 between wirings, removal of a palladium catalyst, and the like are appropriately performed by publicly known methods. In addition, if necessary, an unreacted thermosetting component may be subjected to a post-baking treatment for sufficient thermal curing.

FIG. 1 (f) illustrates a multilayered printed wiring board 100A having a solder resist layer 109 on the outermost surface thereof in which multilayering is achieved by repeating the aforementioned steps.

The solder resist layer 109 can be formed using a publicly known photosensitive resin composition for solder resist.

In the light of the above, while the method for producing a multilayered printed wiring board in which a via is formed using the photosensitive resin composition of the embodiment has been described, since the photosensitive resin composition of the embodiment is excellent in pattern resolution, for example, it is also suitable for forming a cavity for the purpose of internally containing a chip or a passive element, or the like. For example, the cavity can be suitably formed in a manner in which in the aforementioned explanation regarding the multilayered printed wiring board, the drawing pattern during exposing the photosensitive resin film to form a pattern is formed into one capable of forming a desired cavity.

### [Semiconductor Package]

A semiconductor package of the embodiment is a semiconductor package including the multilayered printed wiring board of the embodiment.

The semiconductor package of the embodiment can be produced by mounting a semiconductor element, such as a semiconductor chip and a memory, at a predetermined position of the multilayered printed wiring board of the embodiment and sealing the semiconductor element with a sealing resin, or the like.

### EXAMPLES

Hereinafter, the embodiment will be described in more detail with reference to examples, but the embodiment is not limited to the examples.

### <Method for Measuring Acid Value>

The acid value of the component (A) was calculated from the amount of potassium hydroxide aqueous solution required to neutralize the component (A).

### <Method for Determining Weight Average Molecular Weight and Number Average Molecular Weight>

The weight average molecular weight and the number average molecular weight were determined by performing the measurement using a GPC measurement apparatus as mentioned below and under a measurement condition as also mentioned below and conversion using a calibration curve of standard polystyrene. For preparing the calibration curve, 5 sample sets of standard polystyrene (“PStQuick MP-H” and “PStQuick B”, manufactured by Tosoh Corporation) were used.

### (GPC Measurement Apparatus)

GPC device: High-speed GPC device “HCL-8320GPC”, with a differential refractometer or UV as the detector, manufactured by Tosoh Corporation
Column: Column TSKgel SuperMultipore HZ-H (column length: 15 cm, column inner diameter: 4.6 mm), manufactured by Tosoh Corporation

### (Measurement Condition)

Solvent: Tetrahydrofuran (THF)
Measurement temperature: 40° C.
Flow rate: 0.35 mL/min
Sample concentration: 10 mg/5 mL of THF
Injection volume: 20 μL

### [1. Evaluation of Relative Dielectric Constant (Dk) and Dielectric Dissipation Factor (Df)]

Two photosensitive resin films in which a protective film was peeled from a photosensitive resin film having a carrier film and a protective film produced in each of Examples and Comparative Examples were prepared, and stuck onto each other. Subsequently, while the carrier films on both surfaces thereof were left, exposure was performed at 400 mJ/cm² (wavelength: 365 nm) with a plane exposure device. After that, the carrier films on both surfaces thereof were peeled, irradiation was performed at 2 J/cm² (wavelength: 365 nm) with a conveyor type UV exposure device. A heating treatment at 170° C. for 1 hour was performed with a warm air-circulating dryer, and cutting into a size of 7 cm×10 cm was performed to obtain an evaluation sample.

The obtained evaluation sample was dried at 105° C. for 10 minutes with a warm air-circulating dryer, and the relative dielectric constant (Dk) and the dielectric dissipation factor (Df) were measured at a 10 GHz band by a split post dielectric resonator (SPDR) method.

### [2. Evaluation of Surface Curing Properties]

A protective film was peeled from a photosensitive resin film having a carrier film and a protective film produced in each of Examples and Comparative Examples, and then laminated on a copper-clad laminated substrate having a thickness of 1.0 mm such that the photosensitive resin film became an adhesive surface, to obtain a layered body having the carrier film. The lamination was performed with a press-system vacuum laminator (trade name “MVLP-500” manufactured by Meiki Co., Ltd.) under a condition of a pressure-bonding pressure of 0.4 MPa, a press heating plate temperature of 70 to 80° C., a vacuuming time of 25 seconds, a lamination pressing time of 25 seconds, and an air pressure of 4 kPa or less.

By the same procedure as described above, a layered body having the carrier film was produced, and the carrier film was peeled and removed from the layered body, to obtain a layered body:

Using the layered body having the carrier film and the layered body in which the carrier film was removed, which are obtained above, the following exposure was performed.

### (1) Exposure Condition of Layered Body Having Carrier Film

The entire surface of the layered body having the carrier film was exposed at 500 mJ/cm² from a carrier film side with a parallel light exposure device in which an ultrahigh pressure mercury lamp is used as a light source (trade name “EXM-1201” manufactured by ORC MANUFACTURING CO., LTD.), to cure the photosensitive resin film of the layered body: After that, the carrier film was peeled and removed from the layered body having the carrier film, and development was performed for 60 seconds at a spray pressure of 0.2 MPa using a 1% sodium carbonate aqueous solution. The surface appearance of the resin was then observed.

(2) Exposure Condition of Layered Body without Carrier Film

The entire surface of the layered body in which the carrier film was removed was exposed from a photosensitive resin film side under the same condition as described above, and development was performed for 60 seconds at a spray pressure of 0.2 MPa using a 1% sodium carbonate aqueous solution. The surface appearance of the resin was then observed.

The surfaces of cured products of the photosensitive resin films formed under the exposure conditions (1) and (2) were visually observed, and evaluated in accordance with the following evaluation criteria.
A: The surface of the cured product is luster.
B: The surface of the cured product is not luster.

### [3. Evaluation of Heat Resistance]

The layered body after the development used in the evaluation of “(1) Exposure Condition of Layered Body with Carrier Film” in [2. Evaluation of Surface Curing Properties] was irradiated at 2 J/cm² (wavelength: 365 nm) with a conveyor type UV exposure device, and then subjected to a heating treatment at 170° C. for 1 hour with a warm air-circulating dryer, to obtain a layered body after the heating treatment. The layered body was allowed to remain for 100 hours under a saturated steam condition of 120° C. and 2 atmospheric pressures, and the surface of the layered body, that was, the appearance of the cured product of the photosensitive resin film was visually observed, and evaluated in accordance with the following evaluation criteria.
A: Peeling and blistering are not generated.
B: Peeling or blistering are generated.

### [Preparation of Photosensitive Resin Composition]

### Examples 1 to 10 and Comparative Examples 1 to 5

### (1) Production of Photosensitive Resin Composition

Components were mixed according to a mixing composition shown in Table 1 (in the table, the unit of numerical values is part by mass, and in a case of a solution, part by mass in terms of solid content), and kneaded with a three-roll mill and a planetary centrifugal mixer. After that, methyl ethyl ketone was added such that the solid content concentration was 65% by mass, to obtain a photosensitive resin composition.

### (2) Production of Photosensitive Resin Film

To a carrier film that was a polyethylene terephthalate film (trade name “G2-16” manufactured by Teijin Limited, thickness: 16 μm), the photosensitive resin composition prepared in each of Examples was applied such that the thickness after drying was 25 μm. After that, using a hot air convection dryer, the photosensitive resin composition was dried at 75° C. for 30 minutes, to form a photosensitive resin film having the carrier film.

Subsequently, on a surface opposite to a surface in contact with the carrier film of the photosensitive resin film, a polyethylene film (trade name “NF-15” manufactured by Tamapoly Co., Ltd.) was stuck as a protective film, to obtain a photosensitive resin film having the carrier film and the protective film.

Using the prepared photosensitive resin films, the respective evaluations were performed. The results are shown in Table 1.

TABLE 1

| | | | Example | | | | |
|---|---|---|---|---|---|---|---|
| | | | 1 | 2 | 3 | 4 | 5 |
| Mixing | Component | Compound having carboxy group and | 20.00 | 20.00 | 20.00 | 20.00 | 20.00 |
| composition of | (A) | acryloyl group | | | | | |
| photosensitive | Component | Dipentaerythritol hexaacrylate | 0.81 | 0.81 | 0.81 | 0.81 | 0.81 |
| resin composition | (B) | Trimethylolpropane triacrylate | 3.21 | 3.21 | 3.21 | 3.21 | 3.21 |
| | | Trimethylolpropane trimethacrylate | 4.02 | 4.02 | 4.02 | 4.02 | 4.02 |
| | Component | Polyfunctional maleimide compound | | 8.73 | | | 17.46 |
| | (C) | Polyfunctional allyl compound | | | 6.11 | | |
| | | Polyfunctional nadimide compound | | | | 6.11 | |
| | | Polybutadiene-based elastomer | 0.96 | 0.96 | 0.96 | 0.96 | 0.96 |
| | | having 1,2-vinyl group | | | | | |
| | | Acid anhydride-modified | 2.87 | 2.87 | 2.87 | 2.87 | 2.87 |
| | | polybutadiene | | | | | |
| | Component | 2-[4-(methylthio)benzoyl]-2-(4- | 0.56 | 0.56 | 0.56 | 0.56 | 0.56 |
| | (D) | morpholinyl)propane | | | | | |
| | | 2,4-diethyl thioxanthone | 0.04 | 0.04 | 0.04 | 0.04 | 0.04 |
| | | 4,4′-bis(diethylamino)benzophenone | 0.06 | 0.06 | 0.06 | 0.06 | 0.06 |
| | Component | α,α′-bis(t- | 0.38 | 0.38 | 0.38 | 0.38 | 0.75 |
| | (E) | butylperoxy)diisopropylbenzene | | | | | |
| | Component | Molten silica (volume average | 25.52 | 25.52 | 25.52 | 25.52 | 25.52 |
| | (F) | particle diameter: 0.5 μm) | | | | | |
| | Component | pentaerythritol tetrakis(3- | | | | | |
| | (G) | mercaptobutyrate) | | | | | |
| | Component | Naphthol type epoxy resin | 7.33 | 3.64 | 3.64 | 3.64 | |
| | (H) | Biphenyl aralkyl type epoxy resin | 4.88 | 2.43 | 2.43 | 2.43 | |
| | Component | 1-benzyl-2-phenylimidazole | 0.45 | 0.22 | 0.22 | 0.22 | |
| | (I) | | | | | | |
| | Component | Surface adjustor | 0.07 | 0.07 | 0.07 | 0.07 | 0.07 |
| | (J) | | | | | | |
| Evaluation result | Dielectric | Relative dielectric constant | 3.10 | 2.93 | 2.72 | 2.89 | 2.95 |
| | properties | (Dk) (10 GHz) | | | | | |
| | | Dielectric dissipation factor | 0.0098 | 0.0085 | 0.0073 | 0.0080 | 0.0066 |
| | | (Df) (10 GHz) | | | | | |
| | Surface | Exposure of layered body with | A | A | A | A | A |
| | curing | carrier film | | | | | |
| | properties | Exposure of layered body without | B | B | B | B | B |
| | | carrier film | | | | | |
| | Heat resistance | | A | A | A | A | A |
| | | | Example | | | | |
| | | | 6 | 7 | 8 | 9 | 10 |
| Mixing | Component | Compound having carboxy group and | 20.00 | 20.00 | 20.00 | 20.00 | 20.00 |
| composition of | (A) | acryloyl group | | | | | |
| photosensitive | Component | Dipentaerythritol hexaacrylate | 0.81 | 0.81 | 0.81 | 0.81 | 0.81 |
| resin composition | (B) | Trimethylolpropane triacrylate | 3.21 | 3.21 | 3.21 | 3.21 | 3.21 |
| | | Trimethylolpropane trimethacrylate | 4.02 | 4.02 | 4.02 | 4.02 | 4.02 |
| | Component | Polyfunctional maleimide compound | | | | | |
| | (C) | Polyfunctional allyl compound | 12.22 | | | | |
| | | Polyfunctional nadimide compound | | 12.22 | 12.22 | 12.22 | 12.22 |
| | | Polybutadiene-based elastomer | 0.96 | 0.96 | 0.96 | 0.96 | 0.96 |
| | | having 1,2-vinyl group | | | | | |
| | | Acid anhydride-modified | 2.87 | 2.87 | 2.87 | 2.87 | 2.87 |
| | | polybutadiene | | | | | |
| | Component | 2-[4-(methylthio)benzoyl]-2-(4- | 0.56 | 0.56 | 0.56 | 0.56 | 0.56 |
| | (D) | morpholinyl)propane | | | | | |
| | | 2,4-diethyl thioxanthone | 0.04 | 0.04 | 0.04 | 0.04 | 0.04 |
| | | 4,4′-bis(diethylamino)benzophenone | 0.06 | 0.06 | 0.06 | 0.06 | 0.06 |
| | Component | α,α′-bis(t- | 0.75 | 0.75 | 0.75 | 0.75 | 0.75 |
| | (E) | butylperoxy)diisopropylbenzene | | | | | |
| | Component | Molten silica (volume average | 25.52 | 25.52 | 25.52 | 25.52 | 25.52 |
| | (F) | particle diameter: 0.5 μm) | | | | | |
| | Component | pentaerythritol tetrakis(3- | | | 1.27 | 2.55 | 5.10 |
| | (G) | mercaptobutyrate) | | | | | |
| | Component | Naphthol type epoxy resin | | | | | |
| | (H) | Biphenyl aralkyl type epoxy resin | | | | | |
| | Component | 1-benzyl-2-phenylimidazole | | | | | |
| | (I) | | | | | | |
| | Component | Surface adjustor | 0.07 | 0.07 | 0.07 | 0.07 | 0.07 |
| | (J) | | | | | | |
| Evaluation result | Dielectric | Relative dielectric constant | 2.71 | 2.87 | 2.91 | 2.96 | 2.89 |
| | properties | (Dk) (10 GHz) | | | | | |
| | | Dielectric dissipation factor | 0.0055 | 0.0063 | 0.0065 | 0.0070 | 0.0079 |
| | | (Df) (10 GHz) | | | | | |
| | Surface | Exposure of layered body with | A | A | A | A | A |
| | curing | carrier film | | | | | |
| | properties | Exposure of layered body without | B | B | A | A | A |
| | | carrier film | | | | | |

| | | | | | |
|---|---|---|---|---|---|
| Heat resistance | A | A | A | A | A |

Comparative Example

| | | | 1 | 2 | 3 | 4 | 5 |
|---|---|---|---|---|---|---|---|
| Mixing | Component | Compound having carboxy group and | 20.00 | 20.00 | 20.00 | 20.00 | 20.00 |
| composition of | (A) | acryloyl group | | | | | |
| photosensitive | Component | Dipentaerythritol hexaacrylate | 0.81 | 0.81 | 0.81 | 0.81 | 0.81 |
| resin composition | (B) | Trimethylolpropane triacrylate | 3.21 | 3.21 | 3.21 | 3.21 | 3.21 |
| | | Trimethylolpropane trimethacrylate | 4.02 | 4.02 | 4.02 | 4.02 | 4.02 |
| | Component | Polyfunctional maleimide compound | | 8.73 | 17.46 | | |
| | (C) | Polyfunctional allyl compound | | | | | |
| | | Polyfunctional nadimide compound | | | | | |
| | | Polybutadiene-based elastomer | 0.96 | 0.96 | 0.96 | | |
| | | having 1,2-vinyl group | | | | | |
| | | Acid anhydride-modified | 2.87 | 2.87 | 2.87 | | |
| | | polybutadiene | | | | | |
| | Component | 2-[4-(methylthio)benzoyl]-2-(4- | 0.56 | 0.56 | 0.56 | 0.56 | 0.56 |
| | (D) | morpholinyl)propane | | | | | |
| | | 2,4-diethyl thioxanthone | 0.04 | 0.04 | 0.04 | 0.04 | 0.04 |
| | | 4,4′-bis(diethylamino)benzophenone | 0.06 | 0.06 | 0.06 | 0.06 | 0.06 |
| | Component | α,α′-bis(t- | | | | | |
| | (E) | butylperoxy)diisopropylbenzene | | | | | |
| | Component | Molten silica (volume average | 25.52 | 25.52 | 25.52 | 25.52 | 25.52 |
| | (F) | particle diameter: 0.5 μm) | | | | | |
| | Component | pentaerythritol tetrakis(3- | | | | | |
| | (G) | mercaptobutyrate) | | | | | |
| | Component | Naphthol type epoxy resin | 7.33 | 3.64 | | | 7.33 |
| | (H) | Biphenyl aralkyl type epoxy resin | 4.88 | 2.43 | | | 4.88 |
| | Component | 1-benzyl-2-phenylimidazole | 0.45 | 0.22 | | | 0.45 |
| | (I) | | | | | | |
| | Component | Surface adjustor | 0.07 | 0.07 | 0.07 | 0.07 | 0.07 |
| | (J) | | | | | | |
| Evaluation result | Dielectric | Relative dielectric constant | 3.04 | 3.00 | ND* | 3.25 | 3.30 |
| | properties | (Dk) (10 GHz) | | | | | |
| | | Dielectric dissipation factor | 0.0103 | 0.0095 | ND* | 0.0115 | 0.0120 |
| | | (Df) (10 GHz) | | | | | |
| | Surface | Exposure of layered body with | A | A | A | A | A |
| | curing | carrier film | | | | | |
| | properties | Exposure of layered body without | B | B | B | B | B |
| | | carrier film | | | | | |

| | | | | | |
|---|---|---|---|---|---|
| Heat resistance | A | B | B | B | A |

*In the table, “ND” means that an evaluable cured product cannot be formed due to curing failure.

The details of the component (A), the component (C), the component (H), and the component (J) used in Table 1 are as follows.

### [Component (A)]

Compound having carboxy group and acryloyl group: trade name “ZXR-1889H” manufactured by Nippon Kayaku Co., Ltd., acid value: 110 mg KOH/g, weight average molecular weight: 3,000 to 4,000

### [Component (C)]

Polyfunctional maleimide compound: biphenyl aralkyl type maleimide resin, trade name “MIR-3000” manufactured by Nippon Kayaku Co., Ltd., maleimide group equivalent weight: 393 g/eq
Polyfunctional allyl compound: diallyl isocyanurate compound, trade name “LDAIC” manufactured by Shikoku Chemicals Corporation
Polyfunctional nadimide compound: a compound represented by the following general formula (1)

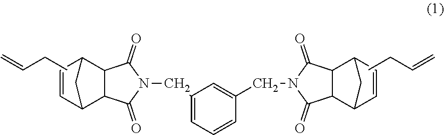

Polybutadiene-based elastomer having a 1,2-vinyl group: butadiene-styrene copolymer, trade name “Ricon100” manufactured by Cray Valley, number average molecular weight: 4,500.
Acid anhydride-modified polybutadiene: trade name “Ricon131MA17” manufactured by Cray Valley, number average molecular weight: 5,400, the number of acid anhydride groups in one molecule: 9
   [Component (H): Epoxy resin]
Naphthol type epoxy resin: trade name “ESN-475V” manufactured by NIPPON STEEL & SUMITOMO METAL CORPORATION, epoxy group equivalent weight: 325 g/eq
Biphenyl aralkyl type epoxy resin: trade name “NC-3000-L” manufactured by Nippon Kayaku Co., Ltd., epoxy group equivalent weight: 272 g/eq
   [Component (J): Other component]
Surface adjustor: silicone foam stabilizer: trade name “SH-193” manufactured by Dow Toray, Co., Ltd.

According to Table 1, the cured products formed from the photosensitive resin compositions in Examples 1 to 10 of the embodiment containing the components (A) to (E) all had a low dielectric dissipation factor (Df) and were excellent in heat resistance.
In Comparative Example 1 without the component (E), the dielectric dissipation factor (Df) was lower than that in Example 1 in which the composition except for the component (E) was the same.
In Comparative Example 2 without the component (E), the dielectric dissipation factor (Df) and heat resistance were lower than those in Example 2 in which the composition except for the component (E) was the same.
In Comparative Example 3 without the component (E), the component (H), and the component (I), an evaluable cured product was not formed due to curing failure.
In Comparative Example 4 without the component (C), the component (E), the component (H), and the component (I), the relative dielectric constant (Dk), the dielectric dissipation factor (Df), and heat resistance were low.
In Comparative Example 5 without the component (C) and the component (E), heat resistance was favorable, but the relative dielectric constant (Dk) and the dielectric dissipation factor (Df) were low.

These results show that according to the photosensitive resin composition of the embodiment, the dielectric dissipation factor (Df) can be improved without reducing heat resistance.

### REFERENCE SIGNS LIST

100A: multilayered printed wiring board
101: Substrate
102: Circuit pattern
103: Photosensitive layer
104: Interlayer insulating layer
105: Via
106: Seed layer
107: Resist pattern
108: Circuit layer of copper
109: Solder resist layer

1. A photosensitive resin composition comprising:
(A) a compound having an acidic substituent and a (meth)acryloyl group;
(B) a (meth)acrylate compound having two or more (meth)acryloyl groups;
(C) a compound having two or more ethylenically unsaturated groups other than the (meth)acryloyl groups;
(D) a photopolymerization initiator; and
(E) an organic peroxide.

2. The photosensitive resin composition according to claim 1, wherein the component (C) is a compound having one or more selected from the group consisting of a maleimide group, an allyl group, a nadimide group, and a vinyl group as the ethylenically unsaturated groups other than the (meth)acryloyl groups.

3. The photosensitive resin composition according to claim 1, wherein the component (C) is a compound having two or more maleimide groups.

4. The photosensitive resin composition according to claim 1, wherein the component (C) is a compound having two or more allyl groups.

5. The photosensitive resin composition according to claim 1, wherein the component (C) is a compound having two or more nadimide groups.

6. The photosensitive resin composition according to claim 1, wherein the component (C) is a compound having two or more vinyl groups.

7. The photosensitive resin composition according to claim 6, wherein the compound having two or more vinyl groups is a polybutadiene-based elastomer having a 1,2-vinyl group.

8. The photosensitive resin composition according to claim 1, further comprising (F) an inorganic filler.

9. The photosensitive resin composition according to claim 1, further comprising (G) a thiol compound.

10. The photosensitive resin composition according to claim 1 which is for photo via formation.

11. The photosensitive resin composition according to claim 1, wherein a dielectric dissipation factor (Df) at 10 GHz of a cured product is 0.0040 to 0.0100.

12. A photosensitive resin film formed using the photosensitive resin composition according to claim 1.

13. The photosensitive resin film according to claim 12, having a thickness of 1 to 100 μm.

14. A multilayered printed wiring board comprising an interlayer insulating layer formed using the photosensitive resin composition according to claim 1.

15. A semiconductor package comprising the multilayered printed wiring board according to claim 14.

16. A method for producing a multilayered printed wiring board comprising (1) to (4) below:
(1): laminating the photosensitive resin film according to claim 12 on one surface or both surfaces of a circuit substrate;
(2): exposing and developing the photosensitive resin film laminated in (1), to form an interlayer insulating layer having a via;
(3): heating and curing the interlayer insulating layer having a via; and
(4): forming a circuit pattern on the interlayer insulating layer.
